(19) United States
(12) Patent Application Publication
(10) Pub. No.: US 2015/0207346 A1
(43) Pub. Date: Jul. 23, 2015

(54) ADDITIONAL BATTERY PACK

(71) Applicant: Nokia Corporation, Espoo (FI)

(72) Inventors: Timo Tapani TOIVOLA, Turku (FI); Juhani KARI, Lieto (FI)

(21) Appl. No.: 14/583,438

(22) Filed: Dec. 26, 2014

(30) Foreign Application Priority Data
Jan. 20, 2014 (GB) 1400867.6

(51) Int. Cl. H02J 7/00; G01R 31/36

(52) U.S. Cl. CPC H02J 7/0014; G01R 31/362; H02J 7/0027

(57) ABSTRACT

The invention relates to an apparatus comprising an autobalancing circuit that is configured to be electrically connected to a first battery and a second battery. The autobalancing circuit is configured to determine voltage difference Vbat1−Vbat2 between the output voltage of the first battery Vbat1 and the output voltage of the second battery Vbat2. If the voltage difference Vbat1−Vbat2 is higher than a predetermined limiting voltage, the autobalancing circuit is configured to limit balancing current between the first battery and the second battery until the output voltage difference is less than the predetermined limiting voltage. The invention further relates to a method and a mobile device comprising the apparatus.

### BACKGROUND

Today's mobile phones and other portable electronic devices offer users a wide range of applications; web access, photos, music and maps are available nearly everywhere. Many of those applications, however, need a large amount of energy, but battery lives of those devices have not kept pace with advances in mobile computing. Therefore, devices using a Lithium-ion battery (Lion) or Lithium-ion polymer (Lipo) battery often consume battery empty in less than one day on heavy use of applications.

### SUMMARY

Now there has been invented an improved technical equipment for increasing battery capacity for a mobile device by adding an additional battery via an autobalancing circuit to an original main battery of the mobile device. Various aspects of the invention include an apparatus and a mobile device which are characterized by what is stated in the independent claims. Various embodiments of the invention are disclosed in the dependent claims.

A replaceable back cover comprising an additional battery structure is suitable to be used instead of the original back cover of a mobile device. An additional battery of the replaceable back cover is arranged to be parallel-coupled to an original main battery of the mobile device temporarily or constantly. An autobalancing circuit of the additional battery structure is arranged to match the additional battery and the main battery together so that inrush current that may damage cells of one or both batteries may be avoided and battery capacity of the additional battery can be added to increase the capacity of the main battery even by full efficiency.

According to a first aspect, there is provided an apparatus comprising: an autobalancing circuit, wherein the autobalancing circuit is configured to be electrically connected to a first battery and a second battery. The autobalancing circuit is configured to determine voltage difference Vbat1−Vbat2 between the output voltage of the first battery Vbat1 and the output voltage of the second battery Vbat2. If the determined voltage difference Vbat1−Vbat2 is higher than a predetermined limiting voltage, the autobalancing circuit is configured to limit balancing current between the first battery and the second battery until the output voltage difference Vbat1−Vbat2 between the first battery and the second battery is less than the predetermined limiting voltage.

According to an embodiment, the autobalancing circuit is configured to limit the balancing current by connecting the batteries in parallel through a limiting resistor. According to an embodiment, the autobalancing circuit is configured to couple the batteries in parallel directly if the output voltage difference Vbat1−Vbat2 is determined to be less than the predetermined limiting voltage. According to an embodiment, the first battery is a main battery of a mobile device and the second battery is an additional battery for the mobile device. According to an embodiment, the second battery is part of the apparatus. According to an embodiment, the apparatus further comprises a cover for the mobile device, wherein the second battery and the autobalancing circuit are attached into the cover. According to an embodiment, the cover is a replacement cover for the mobile device.

According to a second aspect, there is provided a method, comprising: determining voltage difference Vbat1−Vbat2 between an output voltage of a first battery Vbat1 and an output voltage of a second battery Vbat2 by an autobalancing circuit, wherein the autobalancing circuit is configured to be electrically connected to the first battery and the second battery, and limiting balancing current between the first battery and the second battery until the output voltage difference Vbat1−Vbat2 between the first battery and the second battery is less than the predetermined limiting voltage, if the voltage difference Vbat1−Vbat2 is higher than a predetermined limiting voltage, the autobalancing circuit is configured to.

According to an embodiment, the autobalancing circuit is limiting the balancing current by connecting the batteries in parallel through a limiting resistor. According to an embodiment, the method further comprises connecting the batteries in parallel directly, if the output voltage difference Vbat1−Vbat2 is determined to be less than the predetermined limiting voltage.

According to a third aspect, there is provided a computer program product embodied on a non-transitory computer readable medium, comprising computer program code configured to, when executed on at least one processor, cause an apparatus to: determine voltage difference Vbat1−Vbat2 between an output voltage of a first battery Vbat1 and an output voltage of a second battery Vbat2, wherein an autobalancing circuit is configured to be electrically connected to the first battery and the second battery, and limit balancing current between the first battery and the second battery until the output voltage difference Vbat1−Vbat2 between the first battery and the second battery is less than the predetermined limiting voltage, if the voltage difference Vbat1−Vbat2 is higher than a predetermined limiting voltage.

According to an embodiment, the apparatus is caused to limit balancing current by connecting the batteries in parallel through a limiting resistor. According to an embodiment, the apparatus is caused to couple the batteries in parallel directly if the output voltage difference Vbat1−Vbat2 is determined to be less than the predetermined limiting voltage.

According to a fourth aspect, there is provided an apparatus comprising: means for determining voltage difference Vbat1−Vbat2 between an output voltage of a first battery Vbat1 and an output voltage of a second battery Vbat2, and means for limiting balancing current between the first battery and the second battery until the output voltage difference Vbat1−Vbat2 between the first battery and the second battery is less than the predetermined limiting voltage, if the voltage difference Vbat1−Vbat2 is higher than a predetermined limiting voltage.

According to an embodiment, the balancing current is limited by connecting the batteries in parallel through a limiting resistor. According to an embodiment, the apparatus further comprises means for connecting the batteries in parallel directly if the output voltage difference Vbat1−Vbat2 is determined to be less than the predetermined limiting voltage.

### DESCRIPTION OF THE DRAWINGS

In the following, various embodiments of the invention will be described in more detail with reference to the appended drawings, in which

FIG. 1a shows a back-side view of a mobile device with an additional battery structure according to an example embodiment;

FIG. 1b shows a side-view of the mobile device of FIG. 1a according to an example embodiment;

FIG. 2a shows a back-side view of a mobile device with an additional battery structure according to an example embodiment;

FIG. 2b shows a side-view of the mobile device of FIG. 2a according to an example embodiment;

FIG. 3 shows a back-side view of a mobile device with an additional battery structure according to an example embodiment;

FIG. 4a shows a back-side view of a mobile device with an additional battery structure according to an example embodiment;

FIG. 4b shows a side-view of the mobile device of FIG. 4a according to an example embodiment;

FIG. 5a shows an autobalancing circuit of an additional battery structure according to an example embodiment;

FIG. 5b shows an example of a block diagram for the autobalancing circuit shown in FIG. 5a;

FIG. 6a shows an autobalancing circuit of an additional battery structure according to an example embodiment;

FIG. 6b shows an example of a block diagram for the autobalancing circuit shown in FIG. 6a;

FIG. 7 shows a flow chart of a combining method of an additional battery structure with a battery of a mobile device according to an example embodiment; and

FIG. 8 shows a side-view of a mobile device with an additional battery structure according to an example embodiment.

### DESCRIPTION OF EXAMPLE EMBODIMENTS

A time that a mobile device can work on a single charge of a rechargeable battery may be called “battery life”. The battery life may vary substantially depending on, for example, used device, settings, application(s), ambient temperature and/or location, but also, of course, the battery itself; its type and quality etc. Some of the users of mobile devices are so called heavy users that load the device and the battery heavily thereby reducing the battery life. Whereas, some of the users are so called light users who use only a minimum capacity of the mobile device and the battery, thereby their use does not affect the battery life substantially. However, it is also possible that the type of use changes, in some time point there may be a need for high battery capacity and in some time point a smaller capacity is sufficient.

Usually in today's high battery capacity mobile devices for heavy users there is a bigger battery as in the early days of GSM devices. However, a trend and key selling point in today's portable electronic devices, e.g. in mobile phones and other smart devices, has been and continues to be the thinness of the device. Therefore, the big batteries meaning thicker devices may cause difficulties in selling the device and also in usability of the device, at least if there is not a continuous need of bigger batteries.

Instead of a bigger battery in high battery capacity devices, two or more batteries are also used to lengthen the battery time. Two or more battery interfaces may, however, cause high cost for light users who needs only minimum capacity for their use. In addition, a mobile device with two or more battery interfaces would have a space for two or more batteries, even if only one battery is in use (inside the device). Therefore, a mobile device with two or more conventional battery interfaces, whether it is used in a minimum battery capacity mode (with one battery) or a high battery capacity mode (with two or more batteries) has always an appearance of a thicker, heavy use mobile device (two or more batteries).

Further, in today's mobile devices it is possible to use replaceable back covers comprising a high capacity battery for replacing an original battery and back cover of a mobile device. When this kind of cover is used, the mobile device will also have a thicker appearance compared to a mobile device with an original back cover. In addition, this replaceable back cover battery solution needs a special battery interface from the mobile device, accepting different size of batteries, which may be costly and further, the original battery must be discarded as unnecessary when the replaceable back cover comprising a high capacity battery is used.

In the following, several embodiments of the invention will be described in the context of an apparatus for providing energy for a mobile device as an additional battery capacity for the device. It is to be noted, however, that the invention is not limited to mobile devices only. In fact, the different embodiments may have applications widely in any environment where a device needs additional battery capacity. In embodiments of the invention, the apparatus comprising at least an additional battery for providing additional energy, battery capacity, for a battery of a device by parallel coupling and an autobalancing circuit between the batteries, as described throughout the specification, this apparatus comprising the additional battery and the autobalancing circuit may be generally referred to as an additional battery structure.

A mobile device may be a portable device or any other battery-operated device suitable to receive additional battery capacity by parallel coupling an original battery of the device and an additional battery. The mobile device may be, for example, a mobile phone, a mobile computer, a mobile collaboration device, a mobile internet device, a smart phone, a tablet computer, a tablet personal computer (PC), a personal digital assistant, a handheld game console, a portable media player, a digital still camera (DSC), a digital video camera (DVC or digital camcorder), a pager, or a personal navigation device (PND). The invention may be implemented in objects suitable to be attached to such devices, such as in replaceable back covers.

An additional battery structure of the invention provides additional battery capacity for a mobile device. An additional battery of the structure may be electrically coupled parallel to an original battery i.e. main battery of the mobile device through, via, an automatic autobalancing circuit. An automatic balancing function of the automatic autobalancing circuit enables coupling of the additional battery and the battery of the mobile device at any time by an end user of the mobile device. The end user may couple the batteries, for example, by replacing the back cover of the mobile device by a replaceable back cover comprising the additional battery structure when higher battery capacity is needed. The mobile device comprises two contact pins, pads, (battery +/−) where to the automatic autobalancing circuit and the additional battery of the additional battery structure may be connected. The contact pins can be located in the body of the mobile device, for example, in Printed Wiring Board (PWB) or in the main battery. The replaceable back cover may be re-replaced by the original back cover of the mobile device, if needed, for example, if the need for high capacity battery does not exist anymore or if a thinner device is wanted to be used.

The autobalancing circuit connects the additional battery parallel with the main battery of the mobile device, but controls that full battery and empty or damaged battery or batteries with different charge level will non damage each other. The autobalancing circuit may control this by ensuring that voltage difference between the output voltages provided by the two batteries stays within/under a predetermined limiting voltage that may be, for example, 100 mV before it directly connects the batteries together by connecting the positive terminals of the batteries together. When batteries are connected together, their positive terminals of the batteries are connected together. Because, when the output voltage difference between the additional battery and main battery is within the predetermined limiting voltage, for example, equal to or less than the above mentioned 100 mV, direct coupling of the batteries does not cause inrush current that may damage cells of one of the batteries or both batteries. If the output voltage difference is greater than the predetermined limiting voltage, for example, >100 mV, the autobalancing circuit may connect the batteries parallel trough a limiting resistor. The limiting resistor, that may—for example have a resistance of 100Ω, is arranged to limit maximum balancing current between the batteries until batteries have the voltage difference that is equal or less than the predetermined limiting voltage. And when the voltage difference is equal or less than the predetermined limiting voltage, batteries are connected directly parallel, not through the limiting resistor. Batteries remain directly parallel-coupled until the additional battery structure or the replaceable back cover with additional battery structure is removed. When batteries are directly parallel-coupled, the additional battery is fully adding its capacity to use of the mobile device.

As an example, if an additional battery provides max. 4.2V and a main battery provides less than 3V, then an inrush current would be several amperes on direct contact of batteries, possibly tripping protection modules or causing safety risk for cells of one or both of the batteries. Therefore, an autobalancing circuit is arranged to connect the batteries through a limiting resistor of 100Ω for limiting the maximum balancing current between the batteries until batteries have a voltage difference that is less than predetermined limiting voltage 100 mV. When voltage difference is less than predetermined limiting voltage 100 mV, batteries are connected directly parallel, not through the limiting resistor. Batteries remain directly parallel-coupled until the additional battery structure or the replaceable back cover with additional battery structure is removed. When batteries are directly parallel-coupled, the additional battery is fully adding its capacity to use of the mobile device.

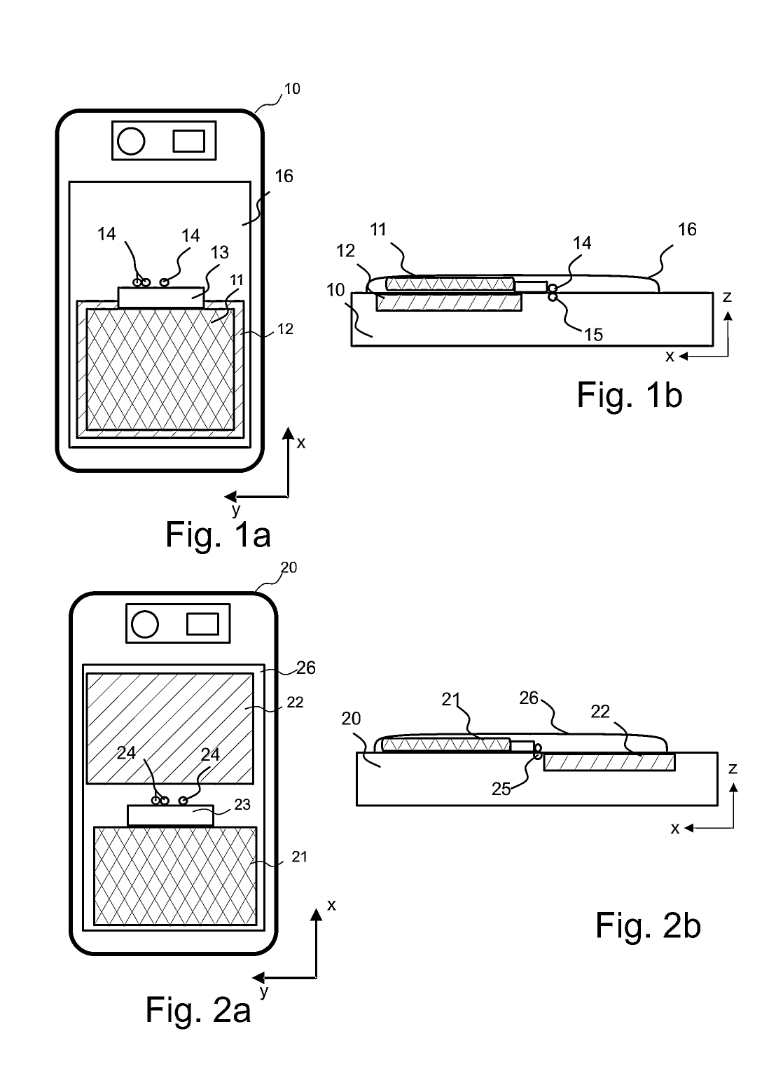

FIG. 1a shows a back-side view of a mobile device 10 with an additional battery structure according to an example embodiment. In this embodiment, when seen from above i.e. in the direction of the normal (z-direction), an additional battery 11 of the additional battery structure is on the main battery 12 of the mobile device 10. The additional battery structure further comprises an autobalancing circuit 13 that is electrically connected to the additional battery 11. The additional battery structure comprises three leads, electrical connection pins 14 that are arranged to be coupled to contact pins 15 (shown in FIG. 1b) of the mobile device 10 for parallel-coupling the batteries 11, 12. One of the pins 14 is a pin of the autobalancing circuit 13 and two of the pins 14 are pins of the additional battery 11 (battery +/−). The additional battery structure comprising the additional battery 11 and the autobalancing circuit 13 is attached to the replaceable back cover 16 of the mobile device 10.

FIG. 1b shows a side-view of the mobile device 10 of FIG. 1a according to an example embodiment. In FIG. 1b is also shown the coupling of connection pins 14 to contact pins 15 of the mobile device 10.

FIG. 2a shows a back-side view of a mobile device 20 with an additional battery structure according to an example embodiment. In this embodiment, when seen from above i.e. in the direction of the normal (z-direction) an additional battery 21 and the main battery 22 do not overlap i.e. the additional battery 21 is next to the main battery 22 and batteries 21, 22 are in the same plane. However, batteries 21, 22 can be also arranged only partly to the same plane.

The additional battery structure further comprises an autobalancing circuit 23 that is electrically connected to the additional battery 21. The additional battery structure comprises three electrical connection pins 24 that are arranged to be coupled to contact pins 25 (shown in FIG. 2b) of the mobile device 20 for parallel-coupling the batteries 21, 22. One of the pins 24 is a pin of the autobalancing circuit 23 and two of the pins 24 are pins of the additional battery 21 (battery +/−). The additional battery structure is attached to the replaceable back cover 26 of the mobile device 20.

FIG. 2b shows a side-view of the mobile device 20 of FIG. 2a according to an example embodiment. In FIG. 2b is shown the coupling of connection pins 24 to contact pins 25 of the mobile device 20.

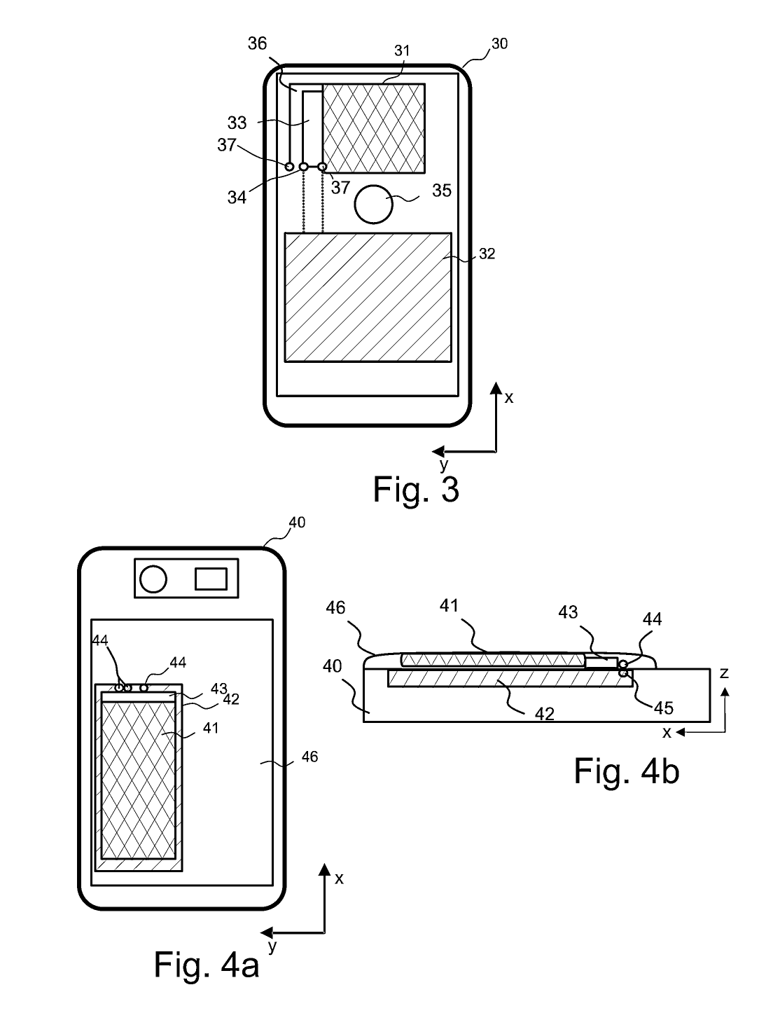

FIG. 3 shows a back-side view of a mobile device 30 with an additional battery structure according to an example embodiment. In this embodiment, when seen from above, an additional battery 31 and a main battery 32 do not overlap i.e. the additional battery 31 is next to the main battery 32, but there is a distance between the batteries 31, 32. In this embodiment the camera 35 is located between the batteries 31, 32.

The additional battery structure further comprises an autobalancing circuit 33 that is electrically connected to the additional battery 31 and arranged next to it. The autobalancing circuit 33 comprises an electrical connection pin 34 and the additional battery 31 comprises two electrical connection pins 37 that are arranged to be coupled to contact pins of the mobile device 30 for parallel-coupling the batteries 31, 32. Contact pins are underneath the connection pins 34 and are not shown in this FIG. 3. The additional battery structure is attached to the replaceable back cover 36 of the mobile device 30.

FIG. 4a shows a back-side view of a mobile device 40 with an additional battery structure according to an example embodiment. In this embodiment, when seen from above, an additional battery 41 of the additional battery structure is on the main battery 42 of the mobile device 40. The additional battery structure further comprises an autobalancing circuit 43 that is electrically connected to the additional battery 41. The additional battery structure comprises three electrical connection pins 44 that are arranged to be coupled to contact pins 45 (shown in FIG. 4b) of the mobile device 40 for parallel-coupling the batteries 41, 42. One of the pins 44 is a pin of the autobalancing circuit 43 and two of the pins 44 are pins of the additional battery 41 (battery +/−). The additional battery structure comprising the additional battery 41 and the autobalancing circuit 43 is attached to the replaceable back cover 46 of the mobile device 40. The autobalancing circuit 43 may be attached to the additional battery 41 or the autobalancing circuit 43 may be just electrically connected to the additional battery 41.

FIG. 4b shows a side-view of the mobile device 40 of FIG. 4a according to an example embodiment. In this embodiment, contact pins 45 for connection pins 44 of the autobalancing circuit 43 are arranged to the main battery 42.

It should be noted that all parts of mobile devices 10, 20, 30, and 40 are not shown in the figures.

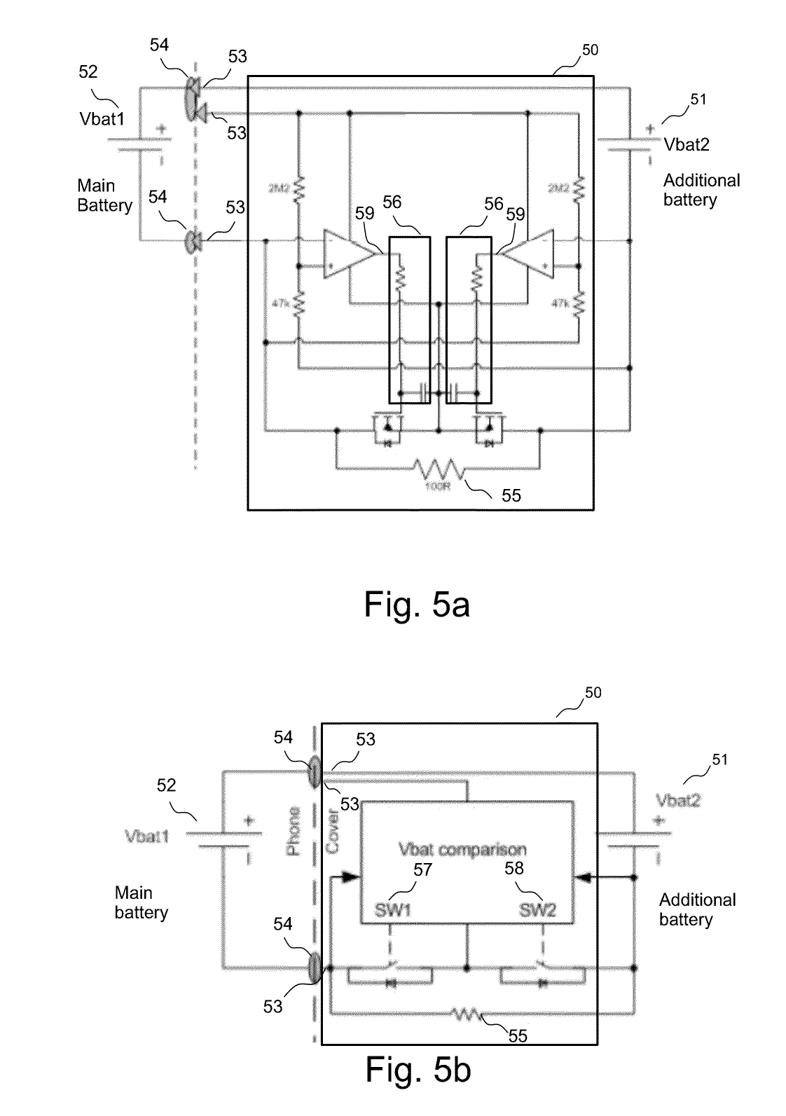

FIG. 5a shows an example of an autobalancing circuit 50 coupled to an additional battery 51 of an additional battery structure according to an example embodiment. The additional battery 51 is connected to a main battery of a mobile device. The autobalancing circuit 50 is arranged between the additional battery 51 of the additional battery structure and a main battery 52 of a mobile device. In FIG. 5a are also shown connection pins 53 of the autobalancing circuit 50 that are connected to contact pins i.e. pads 54 of the main battery 52. A limiting resistor of 100Ω 55 is also shown. In this example, the limiting resistor 55 is coupled between the negative terminal of main battery 53 and the negative terminal of additional battery 51. In this embodiment are further shown resistor-capacitor (RC) filters 56. An RC filter 56 may be coupled to output 59 of at least one of the voltage comparators. The RC filters 56 may prevent false triggering of the limiting function for example in case of short connection spikes or external impulsive interference. The RC filter(s) 56 comprises a resistor and a capacitor, for example with resistance of 1 kΩ and capacitance of 10 nF. The three connection pins 53 are arranged such that the connection pin coupled to the positive terminal of the additional battery and the positive side of the autobalancing circuit 50 are not connected until the additional battery 51 is connected to the mobile device. This reduces the leakage power consumption, because the autobalancing circuit is not connected to the additional battery when the additional battery is not in use.

FIG. 5b shows an example of a block diagram of the circuit of FIG. 5a. The autobalancing circuit 50 determines output voltage difference between (Vbat1−Vbat2). If Vbat1>(Vbat2−100 mV)=>Switch 1 (SW1) 57 is shorted, if Vbat2>(Vbat1−100 mV)=>Switch 2 (SW2) 58 is shorted, and if =>Vbat1−Vbat2=−100 mV . . . +100 mV=SW1 57 and SW2 58 are shorted and batteries are directly parallel coupled. SW1 57 and SW2 58 remains shorted and batteries parallel-coupled until the additional battery is removed from the mobile device. The autobalancing circuit 50 may start a new output voltage difference measurement and balancing when the autobalancing circuit 50 and the additional battery 51 are connected to the main battery 52. And when the autobalancing circuit 50 and the additional battery 51 are removed i.e. at least electrically disconnected from the main battery 52 the autobalancing circuit 50 may reset situation caused by no power on the autobalancing circuit 50, also Vbat2 is then disconnected from the autobalancing circuit 50.

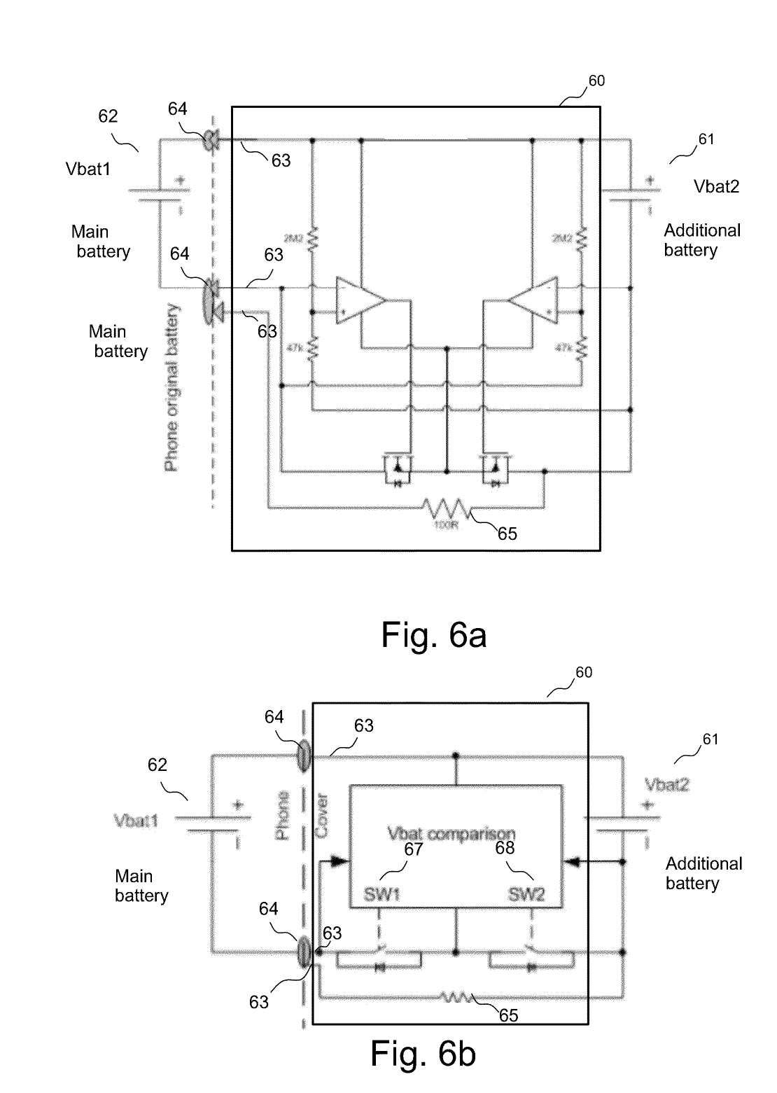

FIG. 6a shows another example of an autobalancing circuit 60 of an additional battery 61 of an additional battery structure according to an example embodiment. The additional battery 61 is connected to a main battery of a mobile device. The autobalancing circuit 60 is arranged between the additional battery 61 of the additional battery structure and a main battery 62 of a mobile device. In FIG. 6a are also shown connection pins 63 of the autobalancing circuit 60 that are electrically connected to contact pads 64 of the main battery 62. A limiting resistor of 100Ω 65 is also shown. The limiting resistor 65 is coupled between the negative terminal of the additional battery 61 and one of the contact pins 63. The arrangement of the contact pins 63 is such that the limiting resistor 65 is not connected to the rest of the autobalancing circuitry until contact pins 63 make contact with contact pads 64 of the main battery 62. FIG. 6b shows an example of a block diagram of FIG. 6a. The autobalancing circuit 60 may also start a new output voltage difference measurement and balancing when the autobalancing circuit 60 and the additional battery 61 are connected to the main battery 62, but after disconnecting the autobalancing circuit 60 and the additional battery 61 from the main battery 62, the autobalancing circuit 60 may keep both switches 1 (SW1) 67 and 2 (SW2) 68 shorted until also Vbat2 is disconnected from the autobalancing circuit 60. If no leak current is allowed during the additional battery storage before use, Vbat2 may be disconnected.

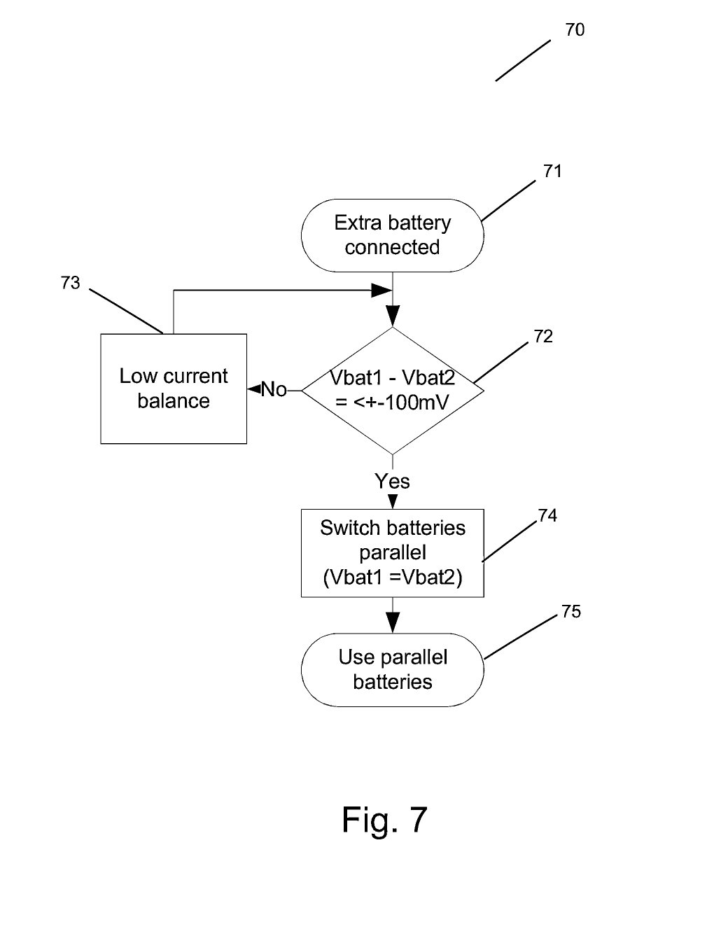

FIG. 7 shows a flow chart of a balancing method 70 of an additional battery structure according to an embodiment. In step 71 the additional battery structure is connected to a main battery of a mobile device. In step 72 the autobalancing circuit determines if difference between output voltage Vbat1 provided by the main battery and output voltage Vbat2 provided by an additional battery of the additional battery structure is less than a predetermined limiting voltage, such as for example 100 mV. If not, the method continues to step 73. In step 73 the autobalancing circuit connects the battery through a limiting resistor until the voltage difference is less that the predetermined limiting voltage, 100 mV. Then the method continues to step 74. In step 74 the autobalancing circuit connects batteries directly together i.e. positive terminals of the batteries are connected together. When batteries are connecting directly together the output voltage Vbat1 provided by the main battery is equal to the output voltage Vbat2 provided by the additional battery. In step 75 batteries are used as parallel. Batteries are parallel used until the additional battery is removed from the mobile device i.e. until the batteries are electrically disconnected.

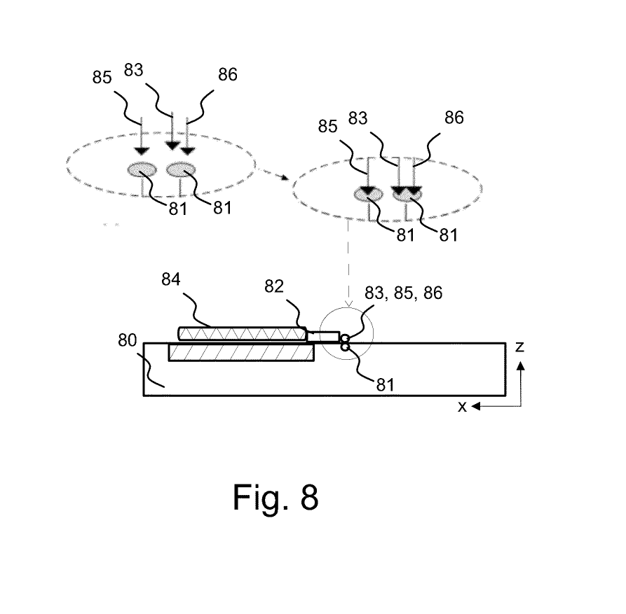

FIG. 8 shows a side-view of a mobile device 80 with an additional battery structure according to an example embodiment. This FIG. 8 shows how three connection pins of the additional battery structure are connected to contact pins, pads, 81 of the mobile device 80. The autobalancing circuit 82 of the additional battery structure comprises one of those connection pins, that is a pin 83, and the additional battery 84 comprises two of those pins, which pins are 85 and 86. Connection pins 83, 85, 86 may be arranged such that there is a gap between connection pin 83 of the autobalancing circuit and a plane defined by connections pins 85, 86 of the additional battery. Therefore, when connecting additional battery 84 and autobalancing circuit 82 to the mobile device 80, connection pins 85, 86 of the additional battery 84 may be connected to the contact pads 81 first and the autobalancing circuit connector 83 may follow shortly after. This connection order may ensure that the positive terminals of the batteries are connected together before balancing and false triggering on beginning may be avoided. As can be seen from FIG. 8, one pad 81 can be arranged for two pins 83, 86 (shared pad is also shown in FIGS. 5a, 5b, 6a and 6b) instead of two separate pads shown in FIG. 1a, 2a, 3 and 4a.

In some embodiments, such as for example illustrated in FIG. 6ab, a similar connection pin arrangement may be used at the negative terminal side. Connection pins 63 may be arranged such that there is a gap between connection pin of the limiting resistor 65 and a plane defined by the other two connection pins.

A back cover comprising an additional battery structure is particularly practical for users whose type of use of a mobile device varies with time. The user may take the replaceable back cover in use when needing to boost the main battery of the device and change it back to original back cover of the mobile device when use is light and extra battery capacity is not needed.

The various embodiments may provide, for example, the following advantages: Hardware requirements of an autobalancing circuit of an additional battery structure such as size and cost are low. There is also no complicated mechanical structure; the additional battery structure is attached to a replaceable back cover by which the additional battery structure can be arranged to the mobile device. Cover electronics, when an additional battery is connected to autobalancing circuit, may consume only <30 uA, so storage time would be years for a battery inside the additional back cover. Whereas, the cover electronics (additional battery structure) may not consume any current when an additional battery is disconnected from an autobalancing circuit inside the additional back cover. When the additional battery is the same type as the main battery, the capacity of the main battery may even be doubled with ˜100% efficiency. Balancing principle of autobalancing circuit does not limit battery capacity of the additional battery and further one or more additional batteries can be added in parallel to a main battery of a mobile device correspondingly in addition to the first additional battery. Main batteries of mobile devices will not be wasted when additional battery structures are used, because use of original main batteries continues. It is obvious that advantages are not limited solely to the above-presented advantages. The additional battery may be charged together with the main battery.

The various embodiments of the invention can be implemented with the help of computer program code that resides in a memory and causes the relevant apparatuses to carry out the invention. For example, an apparatus may comprise circuitry and electronics for determining a voltage difference and limiting balancing current, computer program code in a memory, and a processor that, when running the computer program code, causes the device to carry out the features of an embodiment.

It is obvious that the present invention is not limited solely to the above-presented embodiments, but it can be modified within the scope of the appended claims.

1. An apparatus comprising:
a cover for a mobile device;
an autobalancing circuit attached to the cover, wherein the autobalancing circuit is configured to be electrically connected to a first battery and a second battery, wherein the second battery is attached to the cover, and wherein the autobalancing circuit is configured to determine voltage difference Vbat1−Vbat2 between the output voltage of the first battery Vbat1 and the output voltage of the second battery Vbat2, and if the voltage difference Vbat1−Vbat2 is higher than a predetermined limiting voltage, the autobalancing circuit is configured to limit balancing current between the first battery and the second battery until the output voltage difference Vbat1−Vbat2 between the first battery and the second battery is less than the predetermined limiting voltage.

2. An apparatus according to claim 1, wherein the autobalancing circuit is configured to limit the balancing current by connecting the batteries in parallel through a limiting resistor.

3. An apparatus according to claim 1, wherein the autobalancing circuit is configured to couple the batteries in parallel directly if the output voltage difference Vbat1−Vbat2 is determined to be less than the predetermined limiting voltage.

4. An apparatus according to claim 1, wherein the first battery is a main battery of a mobile device and the second battery is an additional battery for the mobile device.

5. An apparatus according to claim 1, wherein the cover is a replaceable cover for the mobile device.

6. A method, comprising:
determining voltage difference Vbat1−Vbat2 between an output voltage of a first battery Vbat1 and an output voltage of a second battery Vbat2 by an autobalancing circuit, wherein the autobalancing circuit is configured to be electrically connected to the first battery and the second battery, and wherein the second battery and the autobalancing circuit are attached to a cover for a mobile device; and
limiting balancing current between the first battery and the second battery until the output voltage difference Vbat1−Vbat2 between the first battery and the second battery is less than the predetermined limiting voltage, if the voltage difference Vbat1−Vbat2 is higher than a predetermined limiting voltage.

7. A method according to claim 6, wherein the autobalancing circuit is configured to limit the balancing current by connecting the batteries in parallel through a limiting resistor.

8. A method according to claim 6, wherein the method further comprises connecting the batteries in parallel directly, if the output voltage difference Vbat1−Vbat2 is determined to be less than the predetermined limiting voltage.

9. A computer program product embodied on a non-transitory computer readable medium, comprising computer program code configured to, when executed on at least one processor, cause an apparatus to:
determine voltage difference Vbat1−Vbat2 between an output voltage of a first battery Vbat1 and an output voltage of a second battery Vbat2, wherein an autobalancing circuit is configured to be electrically connected to the first battery and the second battery, and wherein the second battery and the autobalancing circuit are attached to a cover for a mobile device; and
limit balancing current between the first battery and the second battery until the output voltage difference Vbat1−Vbat2 between the first battery and the second battery is less than the predetermined limiting voltage, if the voltage difference Vbat1−Vbat2 is higher than a predetermined limiting voltage.

10. A computer program product according to claim 9, wherein the apparatus is caused to limit the balancing current by connecting the batteries in parallel through a limiting resistor.

11. A computer program product according to claim 9, wherein the apparatus is caused to couple the batteries in parallel directly if the output voltage difference Vbat1−Vbat2 is determined to be less than the predetermined limiting voltage.
